(19) United States
(12) Patent Application Publication
(10) Pub. No.: US 2024/0387150 A1
(43) Pub. Date: Nov. 21, 2024

(54) PLASMA ETCHING SYSTEM HAVING FOCUS RING WITH PROLONGED LIFETIME

(71) Applicant: Taiwan Semiconductor Manufacturing Company, Ltd., Hsinchu (TW)

(72) Inventors: Chia-Wei Chen, Chiayi (TW); Chao Yi Chan, Taichung (TW); Yo-Xuan Chen, Taichung (TW); Cheng-Yu Kuo, Taichung (TW); Yen-Yu Chen, Taichung (TW)

(21) Appl. No.: 18/320,219

(22) Filed: May 19, 2023

(51) Int. Cl. H01J 37/32; H01L 21/3065

(52) U.S. Cl. CPC H01J 37/32642; H01J 37/32715; H01L 21/3065; H01J 2237/334

(57) ABSTRACT

An edge assembly used for a plasma etching system is provided. The edge assembly includes: a focus ring peripherally surrounding an edge portion of a mounting platform mounted in the plasma etching system. The focus ring includes: a lower step portion proximate to the edge portion, the lower step portion extending vertically from a bottom surface of the focus ring to a lower step top surface; and an upper step portion distal to the edge portion, the upper step portion extending vertically from the bottom surface of the focus ring to an upper step top surface and extending radially from an upper step inner side to an upper step outer side. The focus ring is characterized by an air gap located in the upper step portion, and the air gap extends peripherally along a circumstance of the focus ring.

### FIELD

Embodiments of the present disclosure relate generally to plasma etching systems, and more particularly to plasma etching systems with improved focus rings.

### BACKGROUND

The semiconductor industry has experienced rapid growth due to ongoing improvements in the integration density of a variety of electronic components (e.g., transistors, diodes, resistors, capacitors, etc.). For the most part, improvement in integration density has resulted from iterative reduction of minimum feature size, which allows more components to be integrated into a given area.

While some integrated device manufacturers (IDMs) design and manufacture integrated circuits (IC) themselves, fabless semiconductor companies outsource semiconductor fabrication to semiconductor fabrication plants or foundries. Semiconductor fabrication consists of a series of processes in which a device structure is manufactured by applying a series of layers onto a substrate. This involves the deposition and removal of various dielectric, semiconductor, and metal layers. The areas of the layer that are to be deposited or removed are controlled through photolithography. Each deposition and removal process is generally followed by cleaning as well as inspection steps. Therefore, both IDMs and foundries rely on numerous semiconductor equipment and semiconductor fabrication materials, often provided by vendors. There is always a need for customizing or improving those semiconductor equipment and semiconductor fabrication materials, which results in more flexibility, reliability, and cost-effectiveness.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a schematic diagram illustrating a cross-sectional view of an example plasma etching system in accordance with some embodiments.

FIG. 2 is a schematic diagram illustrating a cross-sectional view of an example edge assembly in accordance with some embodiments.

FIG. 3 is a schematic diagram illustrating a top view of an example edge assembly in accordance with some embodiments.

FIG. 4 is a diagram illustrating an example plasma sheath region over a focus ring in accordance with some embodiments.

FIG. 5 is a diagram illustrating an example equivalent circuit of the focus ring and the plasma sheath in accordance with some embodiments.

FIG. 6 is a flowchart illustrating an example method for operating a plasma etching system in accordance with some embodiments.

### DETAILED DESCRIPTION OF THE INVENTION

The following disclosure provides many different embodiments, or examples, for implementing different features of the subject matter provided. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In addition, source/drain region(s) may refer to a source or a drain, individually or collectively dependent upon the context. For example, a device may include a first source/drain region and a second source/drain region, among other components. The first source/drain region may be a source region, whereas the second source/drain region may be a drain region, or vice versa. One of ordinary skill in the art would recognize many variations, modifications, and alternatives.

Some embodiments of the disclosure are described. Additional operations can be provided before, during, and/or after the stages described in these embodiments. Some of the stages that are described can be replaced or eliminated for different embodiments. Some of the features described below can be replaced or eliminated and additional features can be added for different embodiments. Although some embodiments are discussed with operations performed in a particular order, these operations may be performed in another logical order.

### Overview

Plasma-related processes are widely used in semiconductor fabrication. For example, plasma etching processes are used very frequently in the rapidly advancing art of semiconductor device fabrication. Reactive ion etching (RIE) or other plasma etching processes are used to etch materials formed on a semiconductor device, typically to create a pattern in a material layer formed on a semiconductor substrate. As another example, plasma cleaning processes are also commonly used in semiconductor device fabrication. Plasma cleaning processes may, for example, include stripping operations used to remove a blanket film of material from a semiconductor device. In addition, plasma-related processes also include plasma treatment processes. Although a plasma etching system used for plasma etching processes is used as an example throughout the disclosure, it should be understood that the techniques disclosed herein are generally applicable to other plasma-related systems used for plasma-related processes.

In a conventional plasma etching system, a focus ring is used to enhance the uniformity of the plasma generated in a chamber by stretching or dragging the plasma horizontally or radially toward the peripheral region of the chamber. However, the materials typically used for the focus ring are prone to attack and degradation in fluorine-based chemistries, which are commonly used in plasma etching processes. Such materials that are prone to attack include quartz, silicon, aluminum, and the like. As a result, the focus ring typically has a relatively short lifetime and requires frequent and lengthy replacement processes, further contributing to the loss in production capacity.

On the other hand, the amount of thermal and electric stress a semiconductor wafer (sometimes also referred to as a “wafer”) incurs during multiple plasma etching processes accumulates rapidly. The semiconductor wafer is typically clamped by an electrostatic chuck (sometimes also referred to as “e-chuck”) so that the semiconductor wafer is “attached” to a wafer holder during the plasma etching processes. A high voltage is typically applied to the electrodes of the electrostatic chuck. The electrostatic field developed due to the high voltage produces an attractive force between the semiconductor wafer and the electrostatic chuck. After plasma hits the semiconductor wafer during the plasma etching process, however, the potential of the semiconductor wafer is typically pulled down to a negative value with respect to the chamber walls within, for example, tens of radio frequency (RF) cycles. As a result, arcing may occur due to a high potential gap, which becomes higher than the breakdown voltage of, for example, a dielectric layer. Arcing may cause damage to or destruction of the semiconductor devices fabricated on the semiconductor wafer and may even render the semiconductor wafer unusable.

In accordance with some aspects of the disclosure, a novel plasma etching system is provided. The plasma etching system includes an edge assembly configured to surround the edge of the semiconductor wafer to be treated in the plasma etching process. The edge assembly includes a focus ring characterized by an air gap. The air gap extends peripherally along the circumference of the focus ring and contains air. Due to the low relative permittivity of the air gap located in the focus ring, the focus ring has a significantly lower capacitance compared with the traditional focus ring without the air gap. Therefore, the potential gap between the focus ring and the plasma sheath generated during the plasma etching process is significantly reduced due to the increased impendence of the focus ring. Accordingly, the thickness of the plasma sheath over the focus ring becomes smaller according to the Child-Langmuir law (sometimes also referred to as the “Child law”). As a result, the erosion of the focus ring by the plasma is reduced; the durability of the focus ring is improved; the lifetime of the focus ring is prolonged. In addition, the unfavorable wafer arcing can also be significantly reduced due to the more uniform plasma and the lower potential gap between the focus ring and the plasma sheath over the wafer.

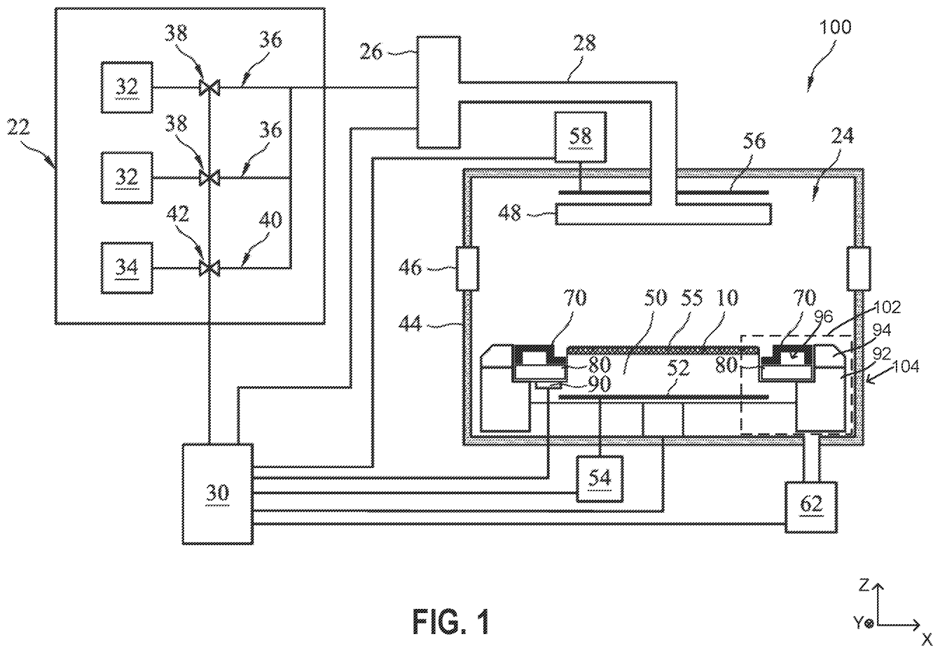

Details of the plasma etching system, the edge assembly, and the focus ring will be described below with references to FIGS. 1-6.

### Example Plasma Etching System Having a Novel Edge Assembly

FIG. 1 is a diagram illustrating an example plasma etching system 100 in accordance with some embodiments. In the example shown in FIG. 1, the plasma etching system 100 includes, among other components, an etchant delivery system 22, an etching chamber 24, an etchant controller 26, a manifold 28, a controller 30, multiple etchant suppliers 32, a carrier gas supply 34, multiple etchant supply lines 36, multiple etchant supply valves 38, a carrier gas supply line 40, a carrier gas supply valve 42, an etchant chamber housing 44, spacers 46, a showerhead 48, a mounting platform 50, a lower electrode 52, a lower RF generator 54, an upper electrode 56, an upper RF generator 58, a vacuum pump 62, and an actuator 90. It should be understood that the plasma etching system 100 may include other components in other embodiments.

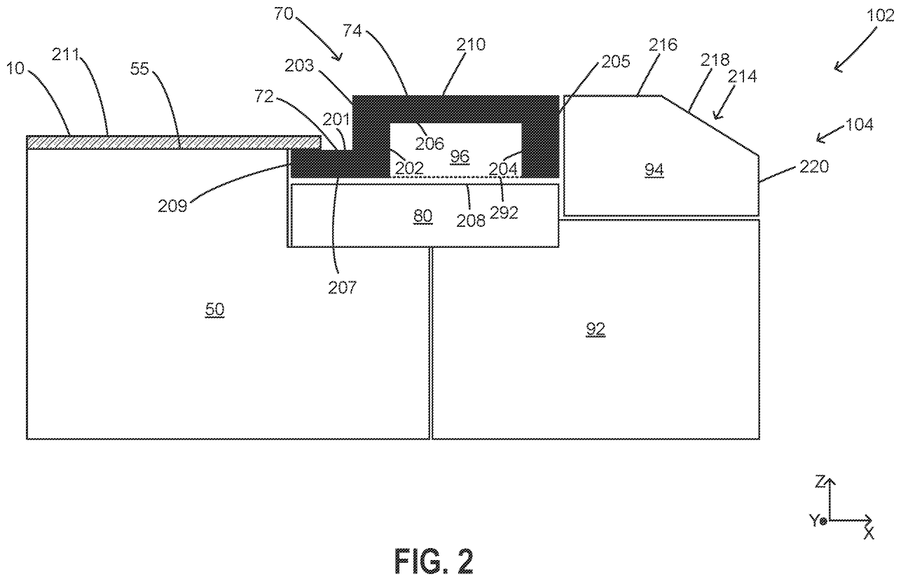

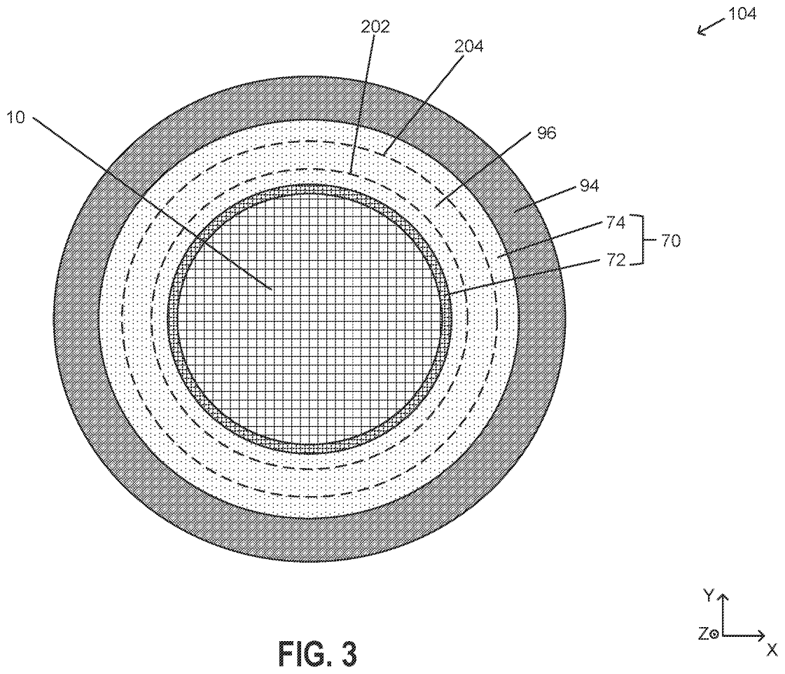

The plasma etching system 100 also includes an edge assembly 104 located in the region 102 (shown within the dashed line in FIG. 1). In the example shown in FIG. 1, the edge assembly 104 is peripherally surrounding an edge or an outer periphery portion of a semiconductor wafer 10 mounted on the mounting platform 50. The edge assembly 104 includes, among other components, an enclosure ring 92, a cover ring 94, a support ring 80, and a focus ring 70. As will be discussed in detail below with reference to FIGS. 2-3, the focus ring 70 has a design featuring an air gap 96, thereby prolonging the lifetime of the focus ring 70.

The etchant delivery system 22 is operable to deliver one or more gaseous etchants to the etching chamber 24. The etchant delivery system 22 supplies the various desired etchants to the etching chamber 24 through the etchant controller 26 and the manifold 28. The etchant delivery system 22 may also help to control the flow rate of the etchant or etchants into the etching chamber 24 by controlling the flow and pressure of a carrier gas through the etchant delivery system 22. The etchant delivery system 22 and the etching chamber 24 are controlled by the controller 30, which controls and regulates the introduction of various etchants and carrier gases to the etching chamber 24. In some embodiments, the plasma etching processes performed by the plasma etching system 100 are reactive-ion etching (RIE) processes or deep reactive-ion etching (DRIE) processes.

In the example shown in FIG. 1, the etchant delivery system 22 includes the etchant suppliers 32 along with the carrier gas supply 34. Although only two of the etchant suppliers 32 are illustrated in FIG. 1, it should be understood that any suitable number of etchant suppliers 32 may be included, such as one etchant supplier for each etchant desired to be used within the plasma etching system 100. For example, in an embodiment in which five separate etchants will be utilized, there may be five etchant suppliers 32.

Each of the etchant suppliers 32 may be a vessel, such as a gas storage tank, that is located either locally to the etching chamber 24 or remotely from the etching chamber 24. In another embodiment, the etchant suppliers 32 may be part of a facility that independently prepares and delivers the desired etchants. Any suitable source for the desired etchants may be utilized as the etchant suppliers 32, and all such sources are fully intended to be included within the scope of the disclosure. Each of the etchant suppliers 32 supplies an etchant to the etchant controller 26 through the etchant supply lines 36 with the etchant supply valves 38. The etchant supply valves 38 are controlled by the controller 30.

The carrier gas supply 34 is operable to supply a desired carrier gas, or diluent gas, that may be used to help push or “carry” the various desired etchants to the etching chamber 24. The carrier gas may be an inert gas or other gas that does not react with the etchant itself or with by-products from the etchant's reactions. For example, the carrier gas may be nitrogen (N2), helium (He), argon (Ar), combinations of these, or the like, although other suitable carrier gases may be utilized in other embodiments.

The carrier gas supply 34 may be a vessel, such as a gas storage tank, that is located either locally to the etching chamber 24 or remotely from the etching chamber 24. In another embodiment, the carrier gas supply 34 may be a facility that independently prepares and delivers the carrier gas to the etchant controller 26. Any suitable source for the carrier gas may be utilized as the carrier gas supply 34, and all such sources are fully intended to be included within the scope of the disclosure. The carrier gas supply 34 may supply the desired carrier gas to the etchant controller 26 through the carrier gas supply line 40 with the carrier gas supply valve 42 that connects the carrier gas supply 34 to the carrier gas supply line 40. The carrier gas supply valve 42 is also controlled by the controller 30 that controls and regulates the introduction of the various etchants and carrier gases to the etching chamber 24. Once combined, the carrier gas and the etchants may be directed toward the etchant controller 26, for a controlled entry into the etching chamber 24 through the manifold 28.

The etching chamber 24 may be any desired shape suitable for dispersing the etchants. In the example shown in FIG. 1, the etching chamber 24 has a cylindrical sidewall and a bottom. However, the etching chamber 24 is not limited to a cylindrical shape, and any other suitable shape, such as a hollow square tube, an octagonal shape, or the like, may be utilized in other embodiments. Furthermore, the etching chamber 24 may be surrounded by the etchant chamber housing 44 made of material that is inert to the various process materials. As such, the etchant chamber housing 44 may be made of any suitable material that can withstand the chemistries and pressures involved in the etching processes. In some embodiments, the etchant chamber housing 44 may be made of steel, stainless steel, nickel, aluminum, alloys of these, combinations of these, and the like. In some embodiments, the spacers 46 may be inserted and removed from the sidewalls of the etchant chamber housing 44 to control the height of the etching chamber 24.

In the example shown in FIG. 1, the etching chamber 24 includes the showerhead 48. In one embodiment, the showerhead 48 receives the various etchants from the manifold 28 and helps to disperse the various etchants into the etching chamber 24. The showerhead 48 may be designed to evenly disperse the etchants in order to minimize undesired process conditions that may arise from uneven dispersal. In one embodiment, the showerhead 48 may have a circular design with openings dispersed evenly around the showerhead 48 to allow for the dispersal of the desired etchants into the etching chamber 24. However, any suitable method of introducing the desired etchants, such as entry ports, may be utilized to introduce the desired etchants into the etching chamber 24.

Within the etching chamber 24 is located the mounting platform 50 in order to position and control the semiconductor wafer 10 during the etching process. In some cases, the semiconductor wafer 10 may be mounted onto a mounting surface 55 of the mounting platform 50. In the example shown in FIG. 1, the mounting platform 50 holds the semiconductor wafer 10 using electrostatic forces, clamps, vacuum pressure, combinations of these, or the like, and may also include heating and cooling mechanisms in order to control the temperature of the semiconductor wafer 10 during the plasma etching processes. In one embodiment, the mounting platform 50 is an e-chuck platform.

In the example shown in FIG. 1, the etching chamber 24 also includes the lower electrode 52 coupled to the lower RF generator 54. The lower electrode 52 may be electrically biased by the lower RF generator 54 (e.g., under the control of the controller 30) at an RF voltage during the plasma etching processes. By being electrically biased, the lower electrode 52 is used to provide a bias to the incoming etchants and assist in igniting them into a plasma. The lower electrode 52 is also utilized to maintain the plasma during the plasma etching processes by maintaining the bias and also to help accelerate ions from the plasma towards the semiconductor wafer 10.

In the example shown in FIG. 1, the etching chamber 24 also includes the upper electrode 56 coupled to the upper RF generator 58, for use as a plasma generator. The upper RF generator 58 provides power to the upper electrode 56 (e.g., under the control of the controller 30) in order to ignite the plasma during the introduction of the reactive etchants. Although the upper electrode 56 is described above as a capacitively coupled plasma generator, embodiments are not intended to be limited to a capacitively coupled plasma generator. Rather, any suitable method of generating the plasma, such as inductively coupled plasma systems, magnetically enhanced reactive ion etching, electron cyclotron resonance, a remote plasma generator, or the like, may be utilized. All such methods are fully intended to be included within the scope of the disclosure.

In the example shown in FIG. 1, the etching chamber 24 is also connected to the vacuum pump 62. In one embodiment, the vacuum pump 62 is under the control of the controller 30 and may be utilized to control the pressure within the etching chamber 24 to the desired pressure. Additionally, once the plasma etching processes are completed, the vacuum pump 62 may be utilized to evacuate the etching chamber 24 in preparation for the removal of the semiconductor wafer 10.

In the example shown in FIG. 1, the actuator 90 is attached to the support ring 80 and is operable to move the support ring 80 and the focus ring 70, for example, vertically. In some embodiments, the actuator 90 may be part of or separate from the support ring 80 or the mounting platform 50. In some embodiments, the actuator 90 may be internal to or external to the etchant chamber housing 44. To move the focus ring 70, the actuator 90 may include, for example, a stepper motor or another type of motor, or a hydraulic system. In some embodiments, the actuator 90 may move a movable part of the support ring 80 directly, or may be connected to the support ring 80 by linkages, gearing, cables, hydraulics, or another suitable technique or combination of techniques. In some embodiments, the actuator 90 is controlled by the controller 30.

Although a number of particular components of the plasma etching system 100 have been described above, other suitable components may also be included. For example, endpoint mounts, liners, and any other components that may help operate or control the plasma etching processes may also be included. All such components are fully intended to be included within the scope of the disclosure.

### Example Edge Assembly Having a Novel Focus Ring

FIG. 2 is a schematic diagram illustrating an example of the edge assembly 104 shown in FIG. 1 in accordance with some embodiments. FIG. 3 is a schematic diagram illustrating a top view of an example of the edge assembly 104 in accordance with some embodiments. As discussed above, the edge assembly 104 located in the region 102 includes, among other components, the enclosure ring 92, the cover ring 94, the support ring 80, and the focus ring 70. The focus ring 70 is characterized by an air gap 96, thereby prolonging the lifetime of the focus ring 70.

In the example shown in FIGS. 2 and 3, the focus ring 70 is peripherally surrounding the semiconductor wafer 10 and has a generally annular shape concentric with the semiconductor wafer 10. The focus ring 70 may have a rectangular cross-sectional shape or may have an irregular cross-sectional shape or a cross-sectional of a different shape. In the illustrated example, the focus ring 70 includes a lower step portion 72 and an upper step portion 74 attached to the lower step portion 72. The lower step portion 72 is proximate to the edge of the semiconductor wafer 10, and the upper step portion 74 is distal to the edge of the semiconductor wafer 10. The upper step portion 74 is elevated in the vertical direction (i.e., the Z-direction shown in FIG. 2) relative to the lower step portion 72 and is larger in dimension than the lower step portion 72.

As shown in FIG. 2, the upper step portion 74 extends from a bottom surface 207 of the focus ring 70 to an upper step top surface 210 in the vertical direction. The upper step portion 74 extends radially from an upper step inner side 203 to an upper step outer side 205 in the horizontal plane (i.e., the X-Y plane). The lower step portion 72 extends vertically from the bottom surface 207 of the focus ring 70 to a lower step top surface 201 and extends radially from a lower step inner side 209 to the upper step inner side 203 of the upper step portion 74. The lower step portion 72 and the upper step portion 74 are connected at the upper step inner side 203 of the upper step portion 74. The lower step top surface 201 is below the upper step top surface 210 in the vertical direction. The distance between the lower step top surface 201 and the upper step top surface 210 may vary depending on design requirements.

As shown in FIG. 2, the lower step inner side 209 is proximate to the mounting platform 50. In some embodiments, the lower step top surface 201 of the lower step portion 72 is coplanar or substantially coplanar with the mounting surface 55. In some embodiments, the edge portion or the outer periphery portion of the semiconductor wafer 10 is located above the lower step portion 72 in the vertical direction. In alternative embodiments, the lower step top surface 201 may be coplanar or substantially coplanar with the top surface 211 of the semiconductor wafer 10. The upper step top surface 210 is above the top surface 211 of the semiconductor wafer 10.

The upper step portion 74 may have a first width (W₁) as measured between the upper step inner side 203 and the upper step outer side 205 and a first thickness (T₁) as measured between the upper step top surface 210 and the bottom surface 207. In some embodiments, the first width (W₁) is from about 17 mm to about 37 mm, or from about 20 mm to about 30 mm, or from about 26 mm to about 28 mm. In one embodiment, the first width (W₁) is about 27 mm. In some embodiments, the first thickness (T₁) is from about 5 mm to about 10 mm, or from about 6 mm to about 9 mm, or from about 7 mm to about 8 mm. In one embodiment, the first thickness (T₁) is about 7.2 mm.

In some embodiments, the lower step portion 72 may have a second width (W₂) as measured from the lower step inner side 209 to the upper step inner side 203 and a second thickness (T₂) as measured between the lower step top surface 201 and the bottom surface 207. In some embodiments, the second width (W₂) is from about 3 mm to about 6 mm, or from about 4 mm to about 5 mm. In one embodiment, the second width (W₂) is about 4.45 mm. In some embodiments, the second thickness (T₂) is from about 2 mm to about 4 mm, or from about 2.5 mm to about 3.5 mm. In one embodiment, the second thickness (T₂) is about 2.8 mm.

In the example shown in FIG. 2, the focus ring 70 is mounted to the support ring 80. The support ring 80 may support or hold the focus ring 70 around an entire circumference of the focus ring 70 or may support or hold the focus ring 70 at one or more separate locations on the focus ring 70. The support ring 80 is disposed partially on the mounting platform 50 and partially on the enclosure ring 92. The support ring 80 has a support ring top surface 208. In some embodiments, both the lower step portion 72 and the upper step portion 74 of the focus ring 70 are disposed on and in contact with the support ring top surface 208.

The focus ring 70 is attached to the cover ring 94. In the illustrated example of FIG. 2, the cover ring 94 is disposed on the upper step outer side 205 of the upper step portion 74 and peripherally surrounding the focus ring 70. The cover ring 94 has a cover ring top surface 216 and a cover ring outer side 220. In some embodiments, the cover ring top surface 216 is coplanar or substantially coplanar with the upper step top surface 210 of the upper step portion 74. In the illustrated example of FIG. 2, the cover ring 94 includes a corner portion 214 having a sloped surface 218. The sloped surface 218 may form smooth edges with the cover ring top surface 216 and the cover ring outer side 220, respectively. The smooth edges of the cover ring 94 may reduce the sharpness of the corner and prevent damage during operation.

The cover ring 94 is mounted to the enclosure ring 92 located below the cover ring 94. The enclosure ring 92 is configured to support and hold the support ring 80 as well as the cover ring 94. As shown in FIG. 2, the enclosure ring 92 is peripherally surrounding the mounting platform 50 and can protect the mounting platform 50 during the plasma etching process.

As mentioned above, the focus ring 70 is characterized by an air gap 96. It should be noted that the term “air gap” used herein is not intended to be limiting and may refer to any space with or without a gas filled therein. Other terms such as “cavity,” “hollow,” “hole,” “channel,” and “recess” are equivalent to “air gap” and may be used interchangeably with “air gap” in the disclosure. For example, as will be discussed below, an “air gap bottom surface” may also be referred to as a “cavity bottom surface;” an “air gap inner side” may also be referred to as a “cavity inner side;” an “air gap outer side” may also be referred to as a “cavity outer side.” One of the ordinary skill in the art would appreciate the interchangeable usage of these terms and other variations.

In one embodiment, the air gap 96 is characterized by a cavity and air filled in the cavity. The relative permittivity (dielectric constant) of air is 1.00058986=0.00000050, very close to that of the vacuum, which is 1. As will be explained below, the low relative permittivity of air in the air gap 96 contributes to a significantly lower capacitance of the focus ring 70 compared with the traditional focus ring without an air gap. Accordingly, the thickness of the plasma sheath over the focus ring 70 becomes smaller, and the erosion of the focus ring 70 by the plasma is reduced.

It should be noted that air gap 96 shown in FIGS. 1-3 is illustrated as only one example and is not intended to be limiting, and other gaps such as a vacuumed cavity or a cavity filled with another gas different from the air are also possible in alternative embodiments. The gas filled in the gap generally has a low relative permittivity (dielectric constant). In one implementation, a back cover located at and coplanar with the bottom surface 207 of the focus ring 70 (and, therefore, the air gap bottom surface 292) is used to seal the gas filled in the cavity or chamber, and the filling and release of the gas can be achieved through, for example, an access opening, which is closed after the filling of the gas. Similarly, the vacuumed cavity mentioned above can also be achieved by a back cover located at the bottom surface 207 of the focus ring 70, and a vacuum pump (e.g., a turbomolecular pump) is connected to the vacuumed cavity through an access opening on the back cover.

As shown in FIG. 3, the air gap 96 extends peripherally within the upper step portion 74 of the focus ring 70 and has an annular shape concentric or substantially concentric with the focus ring 70. In some embodiments, the air gap 96 is continuous along the circumstance thereof. In alternative embodiments, the air gap 96 is segmented, for example, including multiple discrete air gap sections separated from each other along the circumstance of the focus ring 70.

The air gap 96 may have a rectangular cross-sectional shape or a cross-section of a different shape in a radial plane. In the illustrated example of FIG. 2, the air gap 96 extends radially from an air gap inner side 202 to an air gap outer side 204. The air gap 96 is characterized by an air gap bottom surface 292 coplanar with the bottom surface 207 of the focus ring 70. The air gap inner side 202 and the air gap outer side 204 are perpendicular to the bottom surface 207 of the focus ring 70 (and, therefore, the air gap bottom surface 292). The air gap inner side 202 is proximate to the upper step inner side 203 of the upper step portion 74, and the air gap outer side 204 is proximate to the upper step outer side 205 of the upper step portion 74. The air gap 96 extends vertically from an air gap top surface 206 to the bottom surface 207 of the focus ring 70. However, in alternative embodiments, the air gap 96 may be completely enclosed in the upper step portion 74 and not exposed through the bottom surface 207. It should be noted that other cross-sectional shapes, such as circles, squares, ellipses, and rectangles with round corners, are also possible in alternative embodiments.

The air gap 96 has a radial dimension (D) and a vertical dimension (H). The radial dimension (D) is measured by the distance between the air gap inner side 202 and the air gap outer side 204, and the vertical dimension (H) is measured by the distance between the air gap top surface 206 and the bottom surface 207. The cross-sectional dimension of the air gap 96 may vary depending on design requirements.

In some embodiments, the radial dimension (D) of the air gap 96 is from about 5 mm to about 30 mm, or from about 10 mm to about 25 mm, or from about 15 to about 25 mm. In some embodiments, the radial dimension (D) of the air gap 96 is from about 30% to about 90%, or from about 40% to about 80%, or from about 50% to about 70% of the first width (W₁) of the upper step portion 74 of the focus ring 70.

In some embodiments, the vertical dimension (H) of the air gap 96 is from about 20% to about 70%, or from about 30% to about 60%, or from about 40% to about 50% of the first thickness (T₁) of the upper step portion 74 of the focus ring 70.

In one embodiment, the first width (W₁) of the upper step portion 74 is about 27 mm; and the first thickness (T₁) of the upper step portion 74 is about 7.2 mm; the radial dimension (D) of the air gap 96 is 10 mm; the vertical dimension (H) of the air gap 96 is about 2 mm.

In another embodiment, the first width (W₁) of the upper step portion 74 is about 27 mm; and the first thickness (T₁) of the upper step portion 74 is about 7.2 mm; the radial dimension (D) of the air gap 96 is 15 mm, and the vertical dimension (H) of the air gap 96 is about 3 mm.

In yet another embodiment, the first width (W₁) of the upper step portion 74 is about 27 mm; and the first thickness (T₁) of the upper step portion 74 is about 7.2 mm; the radial dimension (D) of the air gap 96 is 20 mm, and the vertical dimension (H) of the air gap 96 is about 4 mm.

The air gap 96 has a first total volume (V₁), and the upper step portion 74 of the focus ring 70 has a second total volume (V₂). In some embodiments, V₁ is about 5% to about 90% of V₂, or from about 20% to about 70% of V₂, or from about 40% to about 50% of V₂.

The focus ring 70 may be made of a conductive material, a semiconductor material, a dielectric material, or another material. In some embodiments, the focus ring 70 may be made of doped or undoped silicon. In some embodiments, the focus ring 70 may be made of quartz, silicon carbide (SiC), or aluminum (Al). In some embodiment, the focus ring 70 may include a coating disposed on an exterior surface thereof (i.e., the lower step top surface 201, the upper step top surface 210, an exterior surface of the upper step inner side 203, and an exterior surface of the upper step outer side 205). The coating may be a metal oxide such as yttrium oxide (Y₂O₃), a metal fluoride such as yttrium fluoride (YF₃), or a metal oxyfluoride such as yttrium oxyfluoride (YOF). The coating may be formed using suitable deposition techniques such as chemical vapor deposition (CVD) or physical vapor deposition (PVD). In some embodiments, the coating may be resistant to degradation in fluorine etching chemistries used in etching, stripping, and cleaning operations in semiconductor manufacturing processes. Thus, the coating may provide additional protection to the focus ring 70 against erosion during, for example, plasma etching processes.

### Improved Performance of the Focus Ring

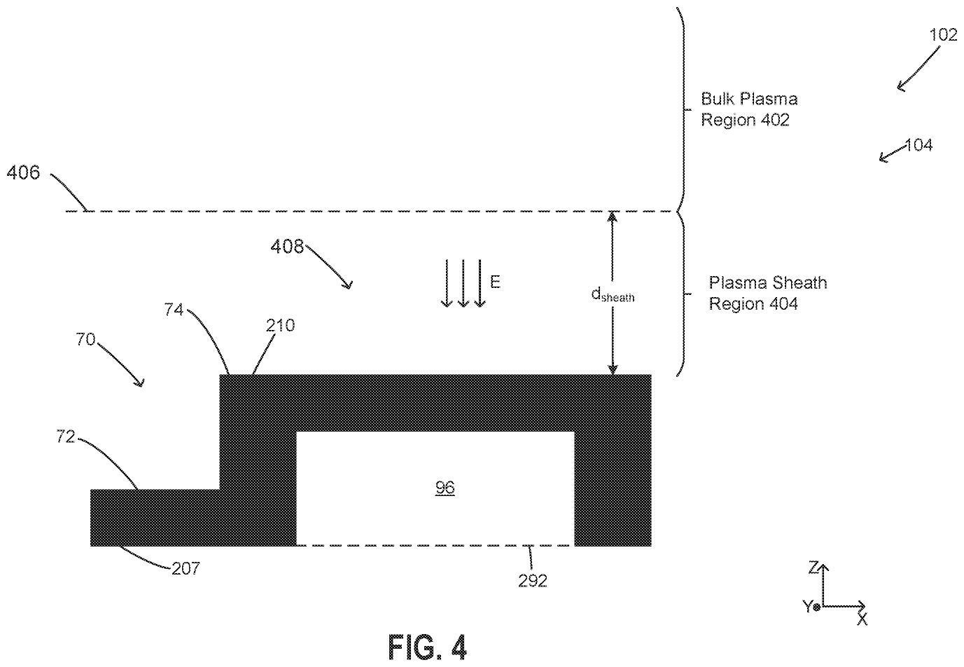

FIG. 4 is a diagram illustrating an example plasma sheath region over a focus ring in accordance with some embodiments. In the example shown in FIG. 4, a bulk plasma region 402 is above a plasma sheath region 404, which is above the focus ring 70. The bulk plasma region 402 and the plasma sheath region 404 have a bulk-sheath interface 406 extending in the horizontal plane (i.e., the X-Y plane shown in FIG. 4).

Plasma is a state of matter in which an ionized substance becomes electrically conductive to the point that long-range electric and magnetic fields dominate its behavior. Plasma is typically an electrically quasi-neutral medium of unbound positive and negative particles (i.e., the overall charge of a plasma is roughly zero). Plasma includes ions and electrons, which are, on average, electrically neutral.

At the edge region of the plasma, electrons leave the plasma before ions do and charge the focus ring 70 (and also the semiconductor wafer 10 shown in FIG. 2). As a result, an electric field (labeled as “E” in FIG. 4) is established at the edge in the Z-direction. The electric field becomes stronger as the electrons charge the focus ring 70 more. Since the electric field is pointing toward the focus ring 70, the electric field retards electrons. In other words, the electric field prevents more electrons from charging the focus ring 70. As such, an equilibrium is eventually reached, and a plasma sheath 408 is developed at the vicinity of the focus ring 70. The plasma sheath 408 is a thin layer of positively charged ions built up over several Debye lengths. In other words, the thickness of the plasma sheath 408 (i.e., the thickness of the plasma sheath region 404, which is labeled as “dₛₕₑₐₜₕ” in FIG. 4) is about several Debye lengths. In one example, the thickness of the plasma sheath 408 is about 0.15 mm. The bulk plasma region 402, on the other hand, is quasi-neutral (i.e., the density of electrons and the density of ions are substantially the same).

On the other hand, ions left behind in the plasma sheath region 404, which are positively charged, are accelerated by the electric field and bombard the focus ring 70. The bombarding energy is proportional to the potential gap (V_{gap}) across the plasma sheath region 404 (i.e., between the focus ring 70 and the bulk-sheath interface 406 and the upper step top surface 210 of the focus ring 70 in the example shown in FIG. 4).

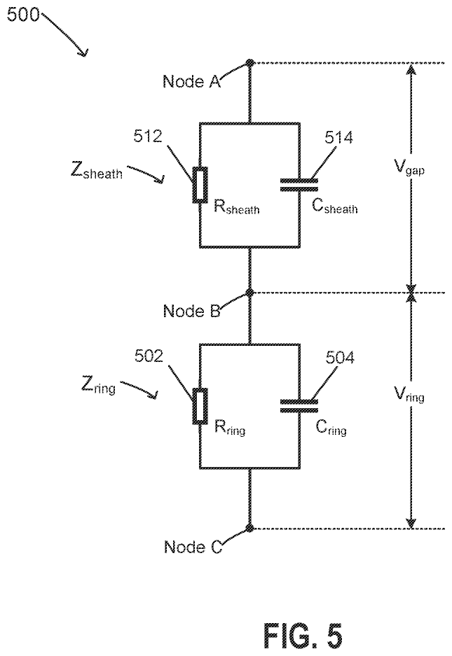

FIG. 5 is a diagram illustrating an example equivalent circuit 500 of the focus ring 70 and the plasma sheath 408 in accordance with some embodiments. The equivalent circuit of the focus ring 70 includes a first resistor 502 (characterized by a resistance R_{ring}) and a first capacitor 504 (characterized by a capacitance C_{ring}) connected in parallel between the Node B and the Node C. The impedance Z_{ring} of the focus ring 70 can be calculated according to the equation (1) below

$$\vert {Z}_{ring} \vert = \frac{1}{\sqrt{{( \frac{1}{{R}_{ring}} )}^{2} + {( ω {C}_{ring} )}^{2}}} \qquad ( 1 )$$

wherein ω is the angular frequency of the RF signal.

Likewise, the equivalent circuit of the plasma sheath 408 includes a second resistor 512 (characterized by a resistance Rₛₕₑₐₜₕ) and a second capacitor 514 (characterized by a capacitance Cₛₕₑₐₜₕ) connected in parallel between the Node A and the Node B. The impedance Zₛₕₑₐₜₕ of the plasma sheath 408 can be calculated according to the equation (2) below

$$\vert {Z}_{s h e a t h} \vert = \frac{1}{\sqrt{{( \frac{1}{{R}_{s h e a t h}} )}^{2} + {( ω {C}_{s h e a t h} )}^{2}}} \qquad ( 2 )$$

wherein ω is the angular frequency of the RF signal.

Since the air in the air gap 96 of the focus ring 70 has a low relative permittivity, the focus ring 70 has a significantly lower capacitance (C_{ring}) compared with the traditional focus ring without an air gap. In one example, the capacitance (C_{ring}) is reduced by about 84% (i.e., to about 16%) compared with the traditional focus ring without an air gap. According to equation (1) above, the impedance of the focus ring 70 increases. As a result, the potential gap (V_{gap}) across the plasma sheath 408 and the potential gap (V_{ring}) across the focus ring 70 are redistributed, and the potential gap (V_{gap}) across the plasma sheath 408 decreases.

In addition, the thickness of the plasma sheath 408 (dₛₕₑₐₜₕ) is proportional to a ¾ exponent of the potential gap (V_{gap}) across the plasma sheath 408, according to the Child-Langmuir law. Since the potential gap (V_{gap}) across the plasma sheath 408 decreases, the thickness of the plasma sheath 408 (dₛₕₑₐₜₕ) decreases as well. According to the parallel plate capacitor formula, the decreased thickness of the plasma sheath 408 (dₛₕₑₐₜₕ) results in the increased capacitance Cₛₕₑₐₜₕ of the second capacitor 514. According to equation (2) above, the increased capacitance Cₛₕₑₐₜₕ further results in the decreased impedance Zₛₕₑₐₜₕ of the plasma sheath 408. The decreased impedance Zₛₕₑₐₜₕ and the increased impedance Z_{ring} reinforce the redistribution of the potential across the focus ring 70 and the plasma sheath 408.

Accordingly, the decreased potential gap (V_{gap}) across the plasma sheath 408 results in a lower erosion rate, since the bombarding energy is proportional to the potential gap (V_{gap}) across the plasma sheath 408, as explained above. The durability of the focus ring 70 is improved; the lifetime of the focus ring 70 is prolonged. On the other hand, the decreased potential gap (V_{gap}) across the plasma sheath 408 also reduces the occurrence of the unfavorable wafer arcing.

In some embodiments, the potential gap between the focus ring 70 and the plasma over the focus ring 70 can be reduced by about 17% to about 47%, compared with the traditional focus ring without the air gap 96. In some embodiments, the erosion rate of the focus ring 70 is reduced by about 23.2% (i.e., to about 76.8%), and the lifetime of the focus ring 70 with the air gap 96 can be improved by at least 90%, compared with the traditional focus ring without the air gap. In some embodiments, the erosion rate of the focus ring 70 with the air gap 96 can be reduced by at least 20%, compared with the traditional focus ring without an air gap. In some embodiments, the arcing rate can be reduced to between about 50 ppm and about 100 ppm, or by more than 95%, as compared with the traditional focus ring without an air gap (the arcing rate of which is generally above 2000 ppm).

### Example Method for Operation a Plasma Etching System

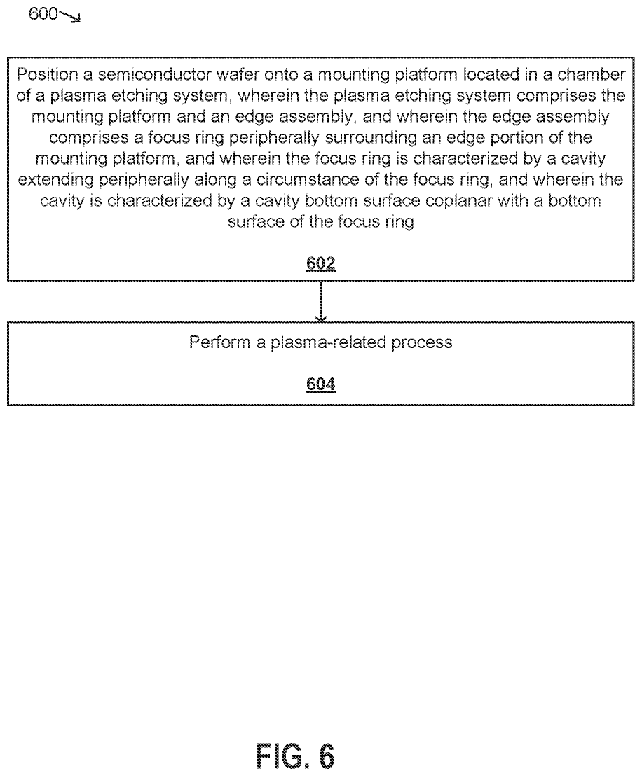

FIG. 6 is a flowchart illustrating an example method 600 for operating a plasma etching system in accordance with some embodiments. In the example shown in FIG. 6, the method 600 includes operations 602 and 604. Additional operations may be performed.

At operation 602, a semiconductor wafer (e.g., the semiconductor wafer 10 shown in FIG. 2) is positioned onto a mounting platform (e.g., the mounting platform 50 shown in FIG. 2) located in a chamber (e.g., the etching chamber 24 shown in FIG. 1) of the plasma etching system (e.g., the plasma etching system 100 shown in FIG. 1). The plasma etching system includes the mounting platform and an edge assembly (e.g., the edge assembly 104 shown in FIG. 2).

The edge assembly includes a focus ring (e.g., the focus ring 70 shown in FIG. 2) peripherally surrounding an edge portion of the mounting platform. The focus ring is characterized by a cavity (e.g., the air gap 96 shown in FIG. 2) extending peripherally along a circumstance of the focus ring. The cavity is characterized by a cavity bottom surface (e.g., the air gap bottom surface 292 shown in FIG. 2) coplanar with a bottom surface (e.g., the bottom surface 207 shown in FIG. 2) of the focus ring.

As explained above, due to the low relative permittivity of the material (e.g., air, vacuum, etc.) located in the cavity, the focus ring has a significantly lower capacitance compared with the traditional focus ring without an air gap. Therefore, the potential gap between the focus ring and the plasma sheath generated during the plasma etching process is significantly reduced due to the increased impendence of the focus ring. As a result, the erosion of the focus ring by the plasma is reduced; the durability of the focus ring is improved; the lifetime of the focus ring is prolonged. In addition, the unfavorable wafer arcing can also be significantly reduced due to the more uniform plasma and the lower potential gap between the focus ring and the plasma sheath over the wafer.

At operation 604, a plasma-related process is performed. In one embodiment, the plasma-related process is a plasma etching process. In another embodiment, the plasma-related process is a plasma cleaning process. In yet another embodiment, the plasma-related process is a plasma treatment process. It should be understood that other types of plasma-related processes may be performed in other embodiments.

### SUMMARY

In accordance with some aspects of the disclosure, an edge assembly used for a plasma etching system is provided. The edge assembly includes: a focus ring peripherally surrounding an edge portion of a mounting platform mounted in the plasma etching system. The focus ring includes: a lower step portion proximate to the edge portion of the mounting platform, the lower step portion extending vertically from a bottom surface of the focus ring to a lower step top surface; and an upper step portion distal to the edge portion of the mounting platform, the upper step portion extending vertically from the bottom surface of the focus ring to an upper step top surface and extending radially from an upper step inner side to an upper step outer side, wherein the lower step portion and the upper step portion are connected at the upper step inner side. The focus ring is characterized by an air gap located in the upper step portion, and the air gap extends peripherally along a circumstance of the focus ring.

In accordance with some aspects of the disclosure, an edge assembly used for a plasma etching system is provided. The edge assembly includes a focus ring peripherally surrounding an edge portion of a mounting platform mounted in the plasma etching system. The focus ring includes an upper step portion. The upper step portion is annular and extends vertically from a bottom surface of the focus ring to an upper step top surface. The upper step portion is characterized by a cavity extending peripherally along a circumstance of the upper step portion, and the cavity is characterized by a cavity bottom surface coplanar with the bottom surface of the focus ring.

In accordance with some aspects of the disclosure, a method for operating a plasma etching system is provided. The method includes the following steps: positioning a semiconductor wafer onto a mounting platform located in a chamber of the plasma etching system, wherein the plasma etching system comprises: the mounting platform; and an edge assembly comprising a focus ring peripherally surrounding an edge portion of the mounting platform, and wherein the focus ring is characterized by a cavity extending peripherally along a circumstance of the focus ring, and wherein the cavity is characterized by a cavity bottom surface coplanar with a bottom surface of the focus ring; and performing a plasma-related process.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. An edge assembly used for a plasma etching system, the edge assembly comprising:
a focus ring peripherally surrounding an edge portion of a mounting platform mounted in the plasma etching system, the focus ring comprising:
a lower step portion proximate to the edge portion of the mounting platform, the lower step portion extending vertically from a bottom surface of the focus ring to a lower step top surface; and
an upper step portion distal to the edge portion of the mounting platform, the upper step portion extending vertically from the bottom surface of the focus ring to an upper step top surface and extending radially from an upper step inner side to an upper step outer side, wherein the lower step portion and the upper step portion are connected at the upper step inner side; and
wherein the focus ring is characterized by an air gap located in the upper step portion, the air gap extending peripherally along a circumference of the focus ring.

2. The edge assembly of claim 1, wherein the air gap is characterized by an air gap bottom surface coplanar with the bottom surface of the focus ring.

3. The edge assembly of claim 2, wherein the air gap extends radially from an air gap inner side to an air gap outer side.

4. The edge assembly of claim 3, wherein the air gap inner side and the air gap outer side are perpendicular to the air gap bottom surface.

5. The edge assembly of claim 1, wherein the air gap is characterized by a rectangular cross section in a radial plane.

6. The edge assembly of claim 1, wherein the air gap is filled with a gas.

7. The edge assembly of claim 6, wherein the gas is air.

8. The edge assembly of claim 1, wherein the focus ring further comprises a back cover coplanar with the bottom surface of the focus ring and enclosing the air gap.

9. The edge assembly of claim 8, wherein the air gap is enclosed to form a vacuumed cavity.

10. The edge assembly of claim 3, wherein the air gap is characterized by a radial dimension between the air gap inner side and the air gap outer side, and the radial dimension is between 30% and 90% of a first width of the upper step portion of the focus ring.

11. The edge assembly of claim 3, wherein the air gap is characterized by a vertical dimension between the air gap bottom surface and an air gap top surface, and the vertical dimension is between 20% and 70% of a first thickness of the upper step portion of the focus ring.

12. The edge assembly of claim 1, further comprising:
a support ring under the focus ring, wherein the focus ring is attached to the support ring; and
an enclosure ring under the support ring, wherein the enclosure ring peripherally surrounds the mounting platform.

13. The edge assembly of claim 12, further comprising:
a cover ring on the enclosure ring, wherein the cover ring peripherally surrounds the focus ring.

14. An edge assembly used for a plasma etching system, the edge assembly comprising:
a focus ring peripherally surrounding an edge portion of a mounting platform mounted in the plasma etching system, wherein the focus ring comprising:
an upper step portion, wherein the upper step portion is annular and extends vertically from a bottom surface of the focus ring to an upper step top surface, and wherein the upper step portion is characterized by a cavity extending peripherally along a circumstance of the upper step portion, and wherein the cavity is characterized by a cavity bottom surface coplanar with the bottom surface of the focus ring.

15. The edge assembly of claim 14, wherein the cavity extends radially from a cavity inner side perpendicular to the cavity bottom surface to a cavity outer side perpendicular to the cavity bottom surface.

16. The edge assembly of claim 14, wherein the focus ring further comprises a back cover coplanar with the bottom surface of the focus ring and enclosing the cavity.

17. The edge assembly of claim 14, wherein the focus ring further comprises:
a lower step portion peripherally surrounding and proximate to the edge portion of the mounting platform, wherein the lower step portion extends vertically from the bottom surface of the focus ring to a lower step top surface, and wherein the lower step portion is attached to the upper step portion.

18. The edge assembly of claim 14, wherein the focus ring comprises silicon.

19. A method for operating a plasma etching system, the method comprising:
positioning a semiconductor wafer onto a mounting platform located in a chamber of the plasma etching system, wherein the plasma etching system comprises:
the mounting platform; and
an edge assembly comprising a focus ring peripherally surrounding an edge portion of the mounting platform, and wherein the focus ring is characterized by a cavity extending peripherally along a circumstance of the focus ring, and wherein the cavity is characterized by a cavity bottom surface coplanar with a bottom surface of the focus ring; and
performing a plasma-related process.

20. The method of claim 19, wherein the plasma-related process is a plasma etching process.
